(19) United States
(12) Patent Application Publication
(10) Pub. No.: US 2025/0309078 A1
(43) Pub. Date: Oct. 2, 2025

(54) SEMICONDUCTOR DIE HAVING A DIE INTERCONNECT AND A DIE LEVEL DISTRIBUTION (DLD) METALLIZATION LAYER INCLUDING A METAL LINE AND A METAL PAD HAVING A WIDTH GREATER THAN THE WIDTH OF THE METAL LINE FOR IMPROVED SIGNAL PATH CONDUCTIVITY BETWEEN THE DIE INTERCONNECT AND THE METAL PAD

(71) Applicant: QUALCOMM Incorporated, San Diego, CA (US)

(72) Inventors: Yangyang Sun, San Diego, CA (US); Wei Hu, San Diego, CA (US); Dongming He, San Diego, CA (US); Lily Zhao, San Diego, CA (US)

(21) Appl. No.: 18/623,118

(22) Filed: Apr. 1, 2024

(51) Int. Cl. H01L 23/498; H01L 23/00; H01L 25/065

(52) U.S. Cl. CPC H01L 23/49822; H01L 23/49816; H01L 24/08; H01L 24/16; H01L 25/0657; H01L 2224/08146; H01L 2224/08225; H01L 2224/16146; H01L 2224/16225; H01L 2225/06513; H01L 2225/0652; H01L 2924/01029; H01L 2924/1421; H01L 2924/1431; H01L 2924/1434; H01L 2924/15311

(57) ABSTRACT

A semiconductor die having a die interconnect and a die level distribution (DLD) metallization layer having a metal line and a metal pad having a width greater than the width of the metal line to support a larger die interconnect for improved signal path conductivity between the die interconnect and the metal pad is disclosed. Related integrated circuit (IC) packages and fabrication methods are also disclosed. The die includes a semiconductor layer, a DLD metallization structure, and a back end of line (BEOL) interconnect structure between the semiconductor layer and the DLD metallization structure. The DLD metallization structure mechanically supports die interconnects for coupling the die to another device, such as a package substrate or another die, and redistributes signals (e.g., power, ground, information) between the die interconnects and the semiconductor layer through the BEOL interconnect structure.

### TECHNICAL FIELD

The field of the disclosure relates to integrated circuit (IC) packages that include one or more semiconductor dies (“dies”) attached to a package substrate, and more particularly to a die level distribution (DLD) metallization structure on a die(s).

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that is mounted on and electrically coupled to a package substrate to provide physical support and an electrical interface to the die(s). The package substrate also includes one or more metallization layers that include metal interconnects (e.g., metal traces, metal lines) with vertical interconnect accesses (vias) coupling the metal interconnects together between adjacent metallization layers to provide electrical interfaces between the die(s). The package substrate also includes an outer metallization layer that includes metal interconnects coupled to external metal interconnects (e.g., ball grid array (BGA) interconnects) to provide an external interface between the dies in the IC package. The external metal interconnects can also be coupled (e.g., soldered) to traces in a printed circuit board (PCB) to attach the package to the PCB and interface its die(s) with the circuitry of the PCB.

The die(s) also includes one or more metallization layers that include metal interconnects (e.g., metal traces, metal lines). The one or more metallization layers are fabricated in the die(s) utilizing a back end of line (BEOL) process. A die level distribution (DLD) metallization layer includes metal interconnects and metal pads. The DLD metallization layer couples to an outer metallization layer which includes metal interconnects fabricated during the BEOL process. The die(s) also includes die interconnects (e.g., balls or pillars) which are supported by metal pads in the DLD metallization layer and electrically couple the metal interconnects in the die(s) to the metal interconnects exposed in the outer metallization layer of the package substrate or another die.

### SUMMARY

Aspects disclosed in the detailed description include a semiconductor die having a die interconnect and a die level distribution (DLD) metallization layer having a metal line and a metal pad having a width greater than the width of the metal line to support a larger die interconnect for improved signal path conductivity between the die interconnect and the metal pad. Related integrated circuit (IC) packages and fabrication methods are also disclosed. The die includes a semiconductor layer, a DLD metallization structure, and a back end of line (BEOL) interconnect structure between the semiconductor layer and the DLD metallization structure. The DLD metallization structure mechanically supports die interconnects for coupling the die to another device, such as a package substrate or another die, and redistributes signals (e.g., power, ground, information) between the die interconnects and the semiconductor layer through the BEOL interconnect structure.

In this regard, the DLD metallization structure includes a DLD metallization layer and a passivation layer disposed between the DLD metallization layer and an outer metallization layer in the BEOL interconnect structure, forming a diffusion barrier therebetween. The DLD metallization layer includes metal pads which mechanically and electrically couple to die interconnects. The DLD metallization layer includes metal lines to route signals to different areas in the die. Vias are formed in the passivation layer to couple metal pads in the DLD metallization layer to metal interconnects in a BEOL interconnect layer in the BEOL interconnect structure. It is desired to reduce the signal path resistance or, conversely, improve signal path conductivity between die interconnects and the metal pads.

In this regard, in exemplary aspects, the metal pads have a width that is greater than the width of the metal lines formed in the DLD metallization layer. The DLD metallization structure is fabricated utilizing conventional dual damascene processes which include a polishing step, such as a chemical mechanical polishing (CMP), to fabricate a smooth coupling surface of the metal pads to die interconnects. CMP can create smooth surfaces to the extent metal features do not extend beyond the width of a metal line. When metal features extend beyond the width of a metal line, the polished surface begins to suffer some dimpling which can impact the resistivity at the smoothed surface. By tolerating some dimpling at the surface of the metal pad, the resistivity caused by some dimpling can be outweighed by the gain in conductivity of an increased area of the surface of the metal pad whose width is greater than the width of the metal line. The increased surface area of the metal pad can couple to a die interconnect with a larger surface area. The wider metal pads thus electrically and mechanically support correspondingly larger die interconnects for improved signal path conductivity therebetween.

In this regard in one aspect, a semiconductor die comprises a die interconnect, a semiconductor layer extending in a first direction, a die level distribution (DLD) metallization structure and a back end of line (BEOL) interconnect structure between the semiconductor layer, and the DLD metallization structure, the BEOL interconnect structure extending in a second direction orthogonal to the first direction and including an outer metallization layer. The DLD metallization structure comprises the outer metallization layer extending in the first direction, a first passivation layer extending in the first direction adjacent to the outer metallization layer, and a DLD metallization layer extending in the first direction and adjacent to the first passivation layer. The DLD metallization layer comprises a metal line extending in the first direction and having a first width in a third direction orthogonal to the second direction and a metal pad disposed in the metal line and having a second width in the third direction which is greater than the first width, the metal pad coupled to the die interconnect.

In another aspect, a method of fabricating a semiconductor die including a die interconnect and a metallization layer including a metal line and a metal pad having a width greater than a width of the metal line for improved signal path conductivity between the die interconnect and the metal pad, comprises fabricating the die interconnect, fabricating a semiconductor layer extending in a first direction, fabricating a die level distribution (DLD) metallization structure, and fabricating a back end of line (BEOL) interconnect structure between the semiconductor layer and the DLD metallization structure, the BEOL interconnect structure extending in a second direction orthogonal to the first direction and including an outer metallization layer extending in the first direction. Fabricating the DLD metallization structure comprises fabricating a first passivation layer extending in the first direction adjacent to the outer metallization layer and fabricating a DLD metallization layer extending in the first direction and adjacent to the first passivation layer. Fabricating the DLD metallization layer comprises fabricating the metal line extending in the first direction and having a first width in a third direction orthogonal to the second direction and fabricating the metal pad disposed in the metal line and having a second width in the third direction which is greater than the first width, the metal pad coupled to the die interconnect.

### BRIEF DESCRIPTION OF THE DRAWINGS

FIG. 1A is a top view of a die level distribution (DLD) metallization layer in a semiconductor die (“die”) having metal lines and metal pads having widths smaller than the width of the metal lines;

FIG. 1B is a side view of a die in FIG. 1A along cut line A₁-A₁;

FIG. 2 is a cross-sectional side view of an exemplary integrated circuit (IC) package that includes a die having a die interconnect and a DLD metallization layer including a metal line and a metal pad having a width greater than the width of the metal line for improved signal path conductivity between the die interconnect and the metal pad;

FIG. 3 is a side view of an IC that includes a die in the IC package of FIG. 2, the die including a die interconnect and a DLD metallization layer including a metal line and a metal pad having a width greater than the width of the metal line for improved signal path conductivity between the die interconnect and the metal pad;

FIG. 4A is a top view of an exemplary DLD metallization layer in a die such as the die in FIG. 3, the DLD metallization layer including a metal line and a metal pad having a width greater than the width of the metal line for improved signal path conductivity between the die interconnect and the metal pad;

FIG. 4B is a top view of another exemplary DLD metallization layer in a die such as the die in FIG. 3, the DLD metallization layer including a metal line and a metal pad having a width greater than the width of the metal line for improved signal path conductivity between the die interconnect and the metal pad;

FIG. 4C is a top view of an exemplary DLD metallization layer in FIG. 4A including a die interconnect having a circular base;

FIG. 4D is a top view of an exemplary DLD metallization layer in FIG. 4B including a die interconnect having an oblong base;

FIG. 5A is a side view of an exemplary embodiment of the die in FIGS. 4A-4D along cut line B₁-B₁ focusing on an exemplary DLD metallization layer which includes a metal line and a metal pad having a width greater than the width of the metal line for improved signal path conductivity between the die interconnect and the metal pad;

FIG. 5B is a side view of an exemplary IC package including the die in FIG. 5A rotated 180° and assembled to a substrate;

FIG. 5C is a side view of another embodiment of the die in FIGS. 4A-4D along cut line C₁-C₁ focusing on an exemplary DLD metallization layer which includes a metal line and a metal pad having a width greater than the width of the metal line for improved signal path conductivity between the die interconnect and the metal pad;

FIG. 5D is a side view of an exemplary IC package including the die in FIG. 5C rotated 180° and assembled to a substrate;

FIG. 6 is a flowchart illustrating an exemplary fabrication process of fabricating a die including a die interconnect and a DLD metallization layer including a metal line and a metal pad having a width greater than the width of the metal line for improved signal path conductivity between the die interconnect and the metal pad, including, but not limited to, the exemplary DLD metallization layers in FIGS. 3 and FIGS. 5A-5D;

FIGS. 7A-7F is a flowchart illustrating another exemplary fabrication process of fabricating a die including a die interconnect and a DLD metallization layer including a metal line and a metal pad having a width greater than the width of the metal line for improved signal path conductivity between the die interconnect and the metal pad, including, but not limited to, the exemplary DLD metallization layers in FIGS. 3 and FIGS. 5A-5D;

FIGS. 8A-8N2 are exemplary fabrication stages during fabrication of the die according to the fabrication process in FIGS. 7A-7F;

FIGS. 9A-9B is a flowchart illustrating an exemplary mass reflow assembly process of assembling a die to a substrate, the die including a die interconnect and a DLD metallization layer including a metal line and a metal pad having a width greater than the width of the metal line for improved signal path conductivity between the die interconnect and the metal pad, including, but not limited to, the exemplary DLD metallization layers in FIGS. 3 and 5A-5D;

FIGS. 10A-10D are exemplary assembly stages for assembling the die to the substrate according to the assembly process in FIGS. 9A-9B;

FIGS. 11A-11B is a flowchart illustrating an exemplary thermal compression assembly process of assembling a die to a substrate, the die including a die interconnect and a DLD metallization layer including a metal line and a metal pad having a width greater than the width of the metal line for improved signal path conductivity between the die interconnect and the metal pad, including, but not limited to, the exemplary DLD metallization layer in FIGS. 3 and 5A-5D;

FIGS. 12A-12D are exemplary assembly stages during assembling the die to the substrate according to the assembly process in FIGS. 11A-11B;

FIG. 13 is a block diagram of an exemplary processor-based system that can include components deployed in an IC package employing a die(s) coupled to a package substrate, wherein the die(s) can include a die interconnect and a DLD metallization layer including a metal line and a metal pad having a width greater than the width of the metal line for improved signal path conductivity between the die interconnect and the metal pad, including, but not limited to, the exemplary dies in FIGS. 3 and 5A-5D, according to the exemplary fabrication processes in FIG. 6 and FIGS. 7A-7F, and according to exemplary assembly processes in FIGS. 9A-9B and 11A-11B; and

FIG. 14 is a block diagram of an exemplary wireless communications device that includes radio-frequency (RF) components deployed in an IC package, wherein the IC package includes a die including a die interconnect and a DLD metallization layer including a metal line and a metal pad having a width greater than the width of the metal line for improved signal path conductivity between the die interconnect and the metal pad, including, but not limited to, the exemplary dies in FIGS. 3 and 5A-5D, according to the exemplary fabrication processes in FIG. 6 and FIGS. 7A-7F, and according to exemplary assembly processes in FIGS. 9A-9B and 11A-11B.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. The term “adjacent” as used herein means spatially next to but not necessarily adjoining something as shown in the Figures unless specifically stated otherwise.

Aspects disclosed in the detailed description include a semiconductor die having a die interconnect and a die level distribution (DLD) metallization layer having a metal line and a metal pad having a width greater than the width of the metal line to support a larger die interconnect for improved signal path conductivity between the die interconnect and the metal pad. Related integrated circuit (IC) packages and fabrication methods are also disclosed. The die includes a semiconductor layer, a DLD metallization structure, and a back end of line (BEOL) interconnect structure between the semiconductor layer and the DLD metallization structure. The DLD metallization structure mechanically supports die interconnects for coupling the die to another device, such as a package substrate or another die, and redistributes signals (e.g., power, ground, information) between the die interconnects and the semiconductor layer through the BEOL interconnect structure.

In this regard, the DLD metallization structure includes a DLD metallization layer and a passivation layer disposed between the DLD metallization layer and an outer metallization layer in the BEOL interconnect structure, forming a diffusion barrier therebetween. The DLD metallization layer includes metal pads which mechanically and electrically couple to die interconnects. The DLD metallization layer includes metal lines to route signals to different areas in the die. Vias are formed in the passivation layer to couple metal pads in the DLD metallization layer to metal interconnects in a BEOL interconnect layer in the BEOL interconnect structure. It is desired to reduce the signal path resistance or, conversely, improve signal path conductivity between die interconnects and the metal pads.

In this regard, in exemplary aspects, the metal pads have a width that is greater than the width of the metal lines formed in the DLD metallization layer. The DLD metallization structure is fabricated utilizing conventional dual damascene processes which include a polishing step, such as a chemical mechanical polishing (CMP), to fabricate a smooth coupling surface of the metal pads to die interconnects. CMP can create smooth surfaces to the extent metal features do not extend beyond the width of a metal line. When metal features extend beyond the width of a metal line, the polished surface begins to suffer some dimpling which can impact the resistivity at the smoothed surface. By tolerating some dimpling at the surface of the metal pad, the resistivity caused by some dimpling can be outweighed by the gain in conductivity of an increased area of the surface of the metal pad whose width is greater than the width of the metal line. The increased surface area of the metal pad can couple to a die interconnect with a larger surface area. The wider metal pads thus electrically and mechanically support correspondingly larger die interconnects for improved signal path conductivity therebetween.

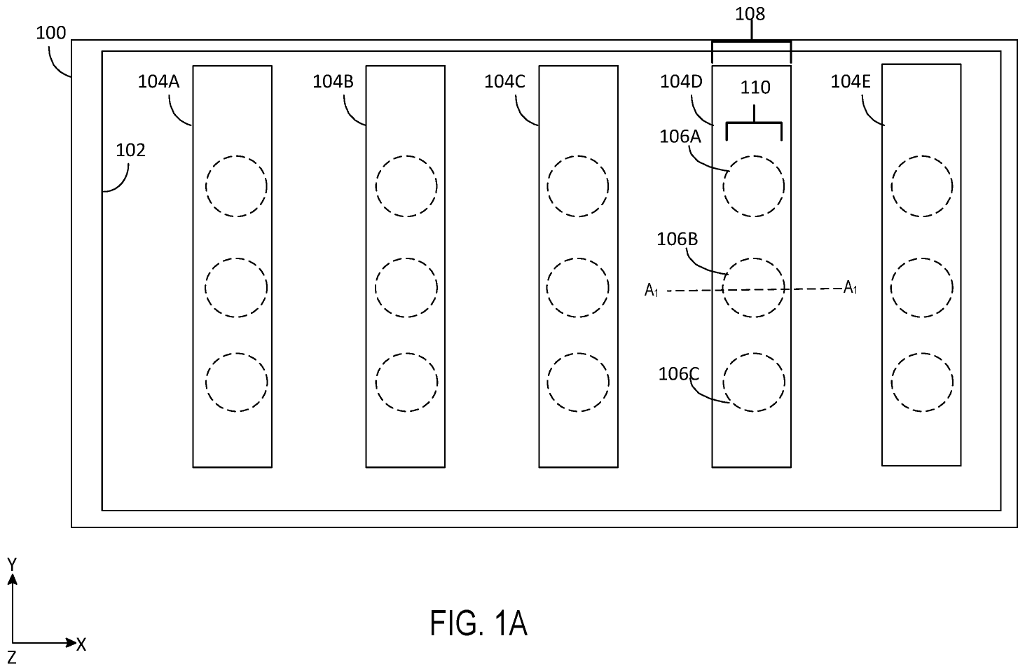

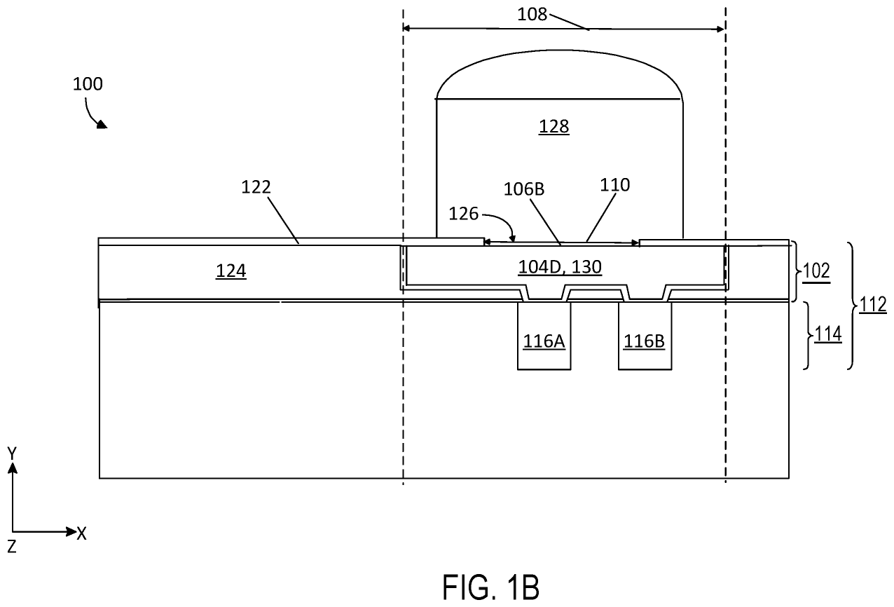

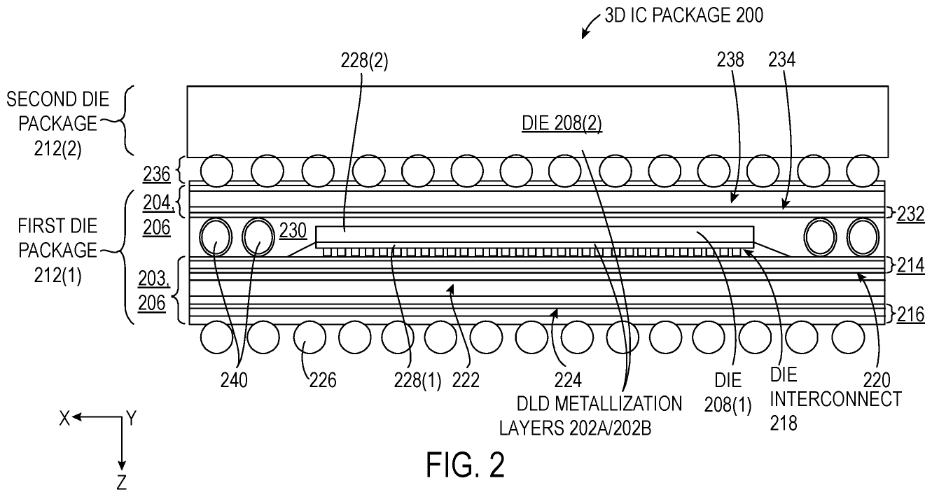

Before discussing exemplary aspects starting at FIG. 2, a conventional die including a DLD metallization layer having metal lines and metal pads where the widths of the metal pads are smaller than the width of the metal lines is first discussed. In this regard, FIG. 1A is a top view of a die level distribution (DLD) metallization layer 102 in a semiconductor die (“die”) 100 having metal lines 104A-104E and under bump landing areas 106A-106C disposed in metal line 104D having widths smaller than the width of the metal lines. The metal lines 104A-104E extend in a first, horizontal direction (Y-axis direction) and have a width 108 in a second, horizontal direction (X-axis direction) of 10 micrometers (μm). The bump landing areas 106A-106C have a width 110 in the second, horizontal direction of 8 μm.

FIG. 1B is a side view of a die, such as the die 100 in FIG. 1A along cut line A₁-A₁. The die 100 includes the DLD metallization layer 102. The die 100 includes a portion of a BEOL interconnect structure 112 which includes a stack of metallization layers illustrated only for simplicity as an outer metallization layer 114 and the DLD metallization layer 102. The outer metallization layer 114 includes metal interconnects 116A-116B. The DLD metallization layer 102 includes a metal line 104D with width 108, bump landing area 106B with width 110, a passivation layer 122, and a dielectric 124. The width 110 of the bump landing area 106B is measured at an opening 126 of the passivation layer 122. The metal line 104D is made of copper (Cu).

The metal line 104D is coupled to the metal interconnects 116A and 116B. The metal line 104D is also coupled to a die interconnect 128 through the opening 126 in the passivation layer 122. The die interconnect 128 is formed in a subsequent bumping process. A metal pad 130 is the portion of the metal line 104D under the periphery of the die interconnect 128. The width of the metal pad 130 is equal to the width of the metal line 104D.

The process of fabricating the die 100 utilizes foundry design rules so that the width 110 of the bump landing area 106B is less than the width 108 of the metal line 104D and the width of the metal pad 130 is no larger than the width 108 of the metal line 104D. During fabrication, a polishing process such as CMP is used to smooth the upper surface of the metal line 104D. By restricting the width of the metal pad 130 to be no greater than the width of the metal line 104D, the upper surface of the metal line 104D and the metal pad 130 can avoid dimpling in the upper surface which can increase resistivity between the die interconnect 128 and the metal pad 130.

If one relaxes the fabrication design rule that requires the width of the metal pad 130 to be no greater than the width of the metal line 104D, more metal can be deployed in the metal pad 130 to allow larger bump landing areas and to support larger die interconnects. By increasing the metal in metal pad 130 and the width of the metal pad 130 beyond the width of the metal line 104D, a larger bump land area is created and, thus, the resistivity is decreased outweighing the increase of resistivity due to possible dimpling at the surface of the metal pad resulting in higher signal path connectivity between the die interconnect and the metal pad.

In this regard, FIG. 2 is a cross-sectional side view of an exemplary IC package that includes a semiconductor die (“die”) having a die interconnect and a DLD metallization layer including a metal line and a metal pad having a width greater than the width of the metal line for improved signal path conductivity between the die interconnect and the metal pad. In this example, the exemplary IC package is a three-dimensional (3D) IC (3DIC) package 200 that includes DLD metallization layers 202A-202B including a metal line and a metal pad having a width greater than the width of the metal line for improved signal path conductivity between the die interconnect and the metal pad. The IC package 200 includes a package substrate 203 and an interposer substrate 204. The package substrate 203 and the interposer substrate 204 commonly route signals and power and, for convenience, may both be referred to simply as a substrate 206.

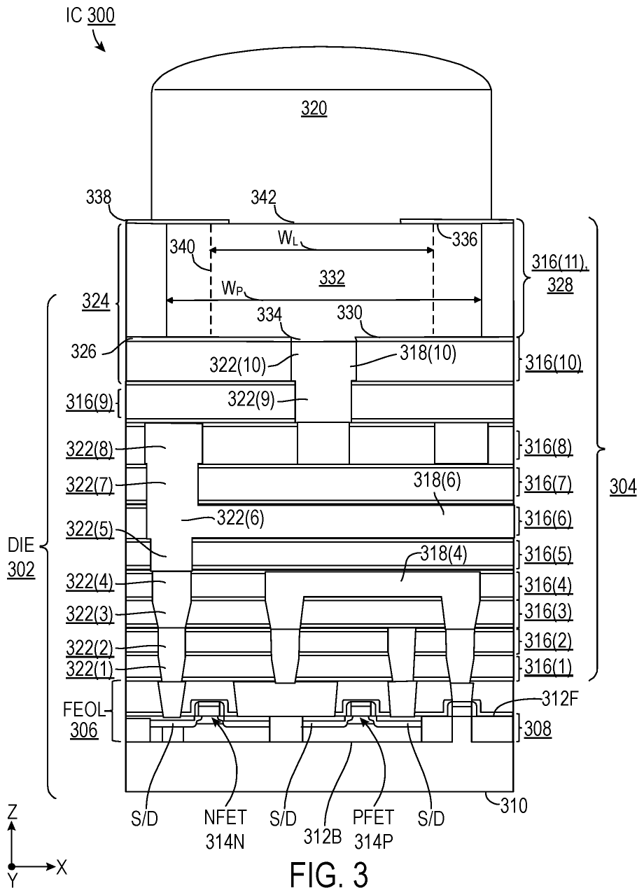

In this example, the IC package 200 includes first and second dies 208(1), 208(2) that are included in respective first and second die packages 212(1), 212(2) that are stacked on top of each other in the vertical direction (Z-axis direction). The first die package 212(1) of the IC package 200 includes the first die 208(1) coupled to the package substrate 203. In this example, the package substrate 203 includes a first, upper and outer metallization layer 214. The first, upper and outer metallization layer 214 provides an electrical interface for signal routing to the first die 208(1). The first die 208(1) is coupled to die interconnects 218 (e.g., raised metal bumps, pillars) that are electrically coupled to metal interconnects 220 in the first, upper and outer metallization layer 214. The first die 208(1) includes the DLD metallization layer 202A which couples the die interconnects 218 to the circuitry within the first die 208(1) and includes a metal line (not visible) and a metal pad (not visible) having a width greater than the width of the metal line for improved signal path conductivity between the die interconnects 218 and the metal pad. The DLD metallization layers 202A-202B will be discussed in more detail in connection with FIGS. 3, 4A-4D, and 5A-5D. The metal interconnects 220 in the first, upper metallization layer 214 are coupled to metal vias 222 (not visible) in the package substrate 203, which are coupled to metal interconnects 224 in a second, bottom and outer metallization layer 216. In this manner, the package substrate 203 provides interconnections between its first and second metallization layers 214 and 216 to provide signal routing to the first die 208(1). The first die 208(1) and the second die 208(2) include the metallization layers 202A and 202B, respectively, and will be discussed in more detail in connection with FIGS. 3, 4A-4D, and 5A-5D. External interconnects 226 (e.g., ball grid array (BGA) interconnects, a.k.a. bumps) are coupled to the metal interconnects 224 in the second, bottom and outer metallization layer 216 to provide interconnections through the package substrate 203 to the first die 208(1) through the die interconnects 218. In this example, a first, active side 228(1) of the first die 208(1) is adjacent to and coupled to the package substrate 203, and more specifically the first, upper and outer metallization layer 214 of the package substrate 203.

In the exemplary IC package 200 in FIG. 2, an additional optional second die package 212(2) is provided and coupled to the first die package 212(1) to support multiple dies. For example, the first die 208(1) in the first die package 212(1) may include an application processor, and the second die 208(2) may be a memory die, such as a dynamic random access memory (DRAM) die that provides memory support for the application processor. In this regard, in this example, the first die package 212(1) also includes the interposer substrate 204 that is disposed on a package mold 230 encasing the first die 208(1), adjacent to a second, inactive side 228(2) of the first die 208(1). The interposer substrate 204 also includes one or more metallization layers 232 that each include metal interconnects 234 to provide interconnections to the second die 208(2) in the second die package 212(2). The second die package 212(2) is physically and electrically coupled to the first die package 212(1) by being coupled through external interconnects 236 (e.g., solder bumps, BGA interconnects) to the interposer substrate 204. The external interconnects 236 are coupled to the metal interconnects 234 in the interposer substrate 204 through metal vias 238 (not visible). The first die package 212(1) includes vertical interconnects 240 to couple the second die 208(2) to the external interconnects 226 and to the first die 208(1) through the package substrate 203. The second die 208(2) also includes a DLD metallization layer 202B which couples the external interconnects 236 to the circuitry within the second die 208(2) and includes a metal line (not visible) and a metal pad (not visible) having a width greater than the width of the metal line for improved signal path conductivity between the external interconnects 236 and the metal pad. The DLD metallization layers 202A-202B will be discussed in more detail in connection with FIGS. 3, 4A-4D, and 5A-5D.

FIG. 3 is a side view of an IC 300 that includes a die 302 such as the die 208(1) or the die 208(2) of FIG. 2, the die 302 including a die interconnect and a DLD metallization layer including a metal line and a metal pad having a width greater than the width of the metal line for improved signal path conductivity between the die interconnect and the metal pad. The die 302 includes a BEOL interconnect structure 304 formed by a BEOL process and disposed on a front-end-of-line (FEOL) structure 306. The FEOL structure 306 includes an active, semiconductor layer 308 that is formed on a substrate 310. The semiconductor layer 308 extends in a first, horizontal direction, which is the X-axis and Y-axis directions as shown in FIG. 3. The semiconductor layer 308 has a first, front side 312F and a second, back side 312B opposite of the first, front side 312F in the second, vertical direction (Z-axis direction). P-type field-effect transistors (FETs) (PFETs) and N-type FETs (NFETs) 314P, 314N are formed in the semiconductor layer 308. The BEOL interconnect structure 304, as a front side interconnect structure 304, is disposed adjacent to the front side 312F of the semiconductor layer 308 in the second, vertical direction (Z-axis direction). The BEOL interconnect structure 304 facilitates signal routing in the die 302 on the front side 312F of the semiconductor layer 308. In this regard, the BEOL interconnect structure 304 includes a plurality of front side, metallization layers 316(1)-316(11) that each include one or more metal interconnects 318(1)-318(11) that can provide direct or indirect interconnections between the FETs 314P, 314N and a die interconnect 320 (e.g., a solder bump) adjacent to an upper metallization layer 316(11) of the BEOL interconnect structure 304. The metal interconnects 318(1)-318(11) extend in the first, horizontal direction(s) (X- and/or Y-axis directions). The BEOL interconnect structure 304 also includes via layers 322(1)-322(11) disposed through the front side metallization layers 316(1)-316(11) to provide interconnects between metal interconnects 318(1)-318(11) in adjacent metallization layers 316(1)-316(11).

With continuing reference to FIG. 3, a DLD metallization structure 324 includes the outer metallization layer 316(10) extending in the first, horizontal direction (X-, Y-axes direction). The outer metallization layer 316(10) includes metal interconnect 318(10). The DLD metallization structure 324 also includes a first passivation layer 326 extending in the first, horizontal direction adjacent to the outer metallization layer 316(10). The DLD metallization structure 324 also includes metallization layer 316(11), also referred to as a DLD metallization layer 328, extending in the first, horizontal direction. The DLD metallization layer 328 is composed of copper and is adjacent to the first passivation layer 326. The DLD metallization layer 328 is the thickest layer in the die 302, and comprises metal interconnects including metal lines, metal traces, and metal pads extending in the first horizontal direction. Metal pads mechanically and electrically couple die interconnects to the outer metallization layer 316(10), and distribute signals (power, ground, information) therebetween. The DLD metallization layer 328 also distributes signals between die interconnects on the periphery of the die 302 to interconnects in the outer metallization layer 316(1) in the interior of the die 302. The DLD metallization layer 328 includes a first surface 330 adjacent to the first passivation layer 326. The DLD metallization structure 324 also includes a first via 334 extending in the second, vertical direction (Z-axis direction) orthogonal to the first direction, the first via 334 coupling a metal pad 332 and the metal interconnect 318(10).

The DLD metallization layer 328 has a second surface 336 opposite the first surface 330. The DLD metallization layer 328 includes a second passivation layer 338 extending in the first, horizontal direction adjacent to the second surface 336 of the DLD metallization layer 328. The DLD metallization layer 328 includes a metal line 340 extending in the first, horizontal direction (X-, Y-axes direction) and having a first width, W_{L}, in a third, horizontal direction (X-axis direction) orthogonal to the second direction (Z-axis direction). The metal pad 332 is disposed in the metal line 340 and has a second width, Wp, in the third, horizontal direction which is greater than the first width, W_{L}. The second passivation layer 338 includes a passivation opening 342 coupling the metal pad 332 to the die interconnect 320.

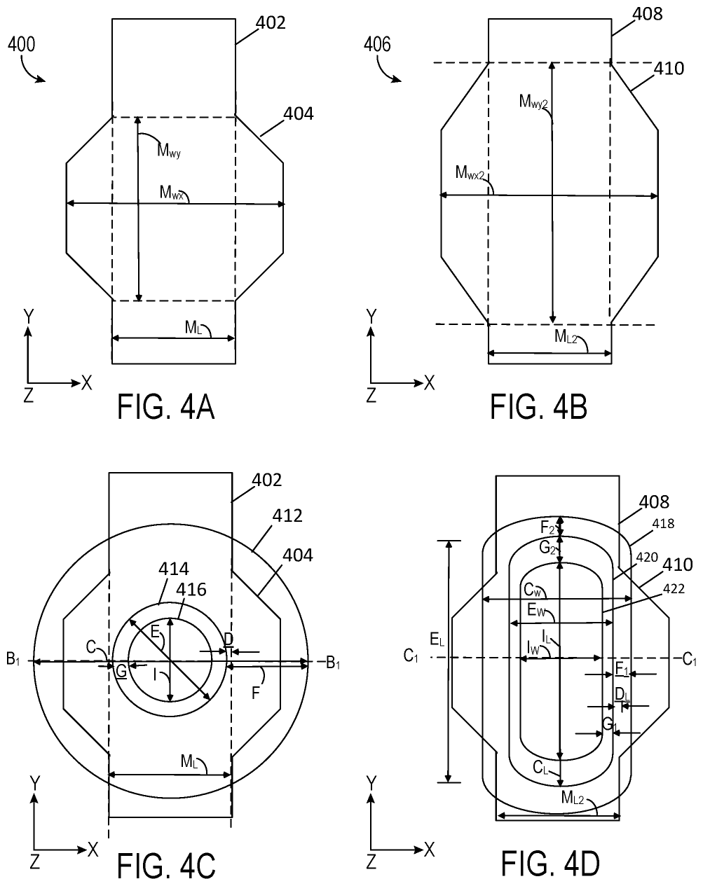

FIG. 4A is a top view of an exemplary DLD metallization layer 400 in a die such as the die 302 in FIG. 3, the DLD metallization layer 400 including a metal line 402 and a metal pad 404 disposed in the metal line 402 having a width, M_{wx}, greater than the width of the metal line, M_{L}, for improved signal path conductivity between a die interconnect and the metal pad 404. The metal pad 404 has a uniform octagonal shape where the width, M_{wx}, in the X-axis direction equal to the width, M_{wy}, in the Y-axis direction.

FIG. 4B is a top view of another exemplary DLD metallization layer 406 in a die such as the die 302 in FIG. 3, the DLD metallization layer 406 including a metal line 408 and a metal pad 410 disposed in the metal line 408 having a width, M_{wx2}, greater than the width of the metal line, M_{L2}, for improved signal path conductivity between a die interconnect and the metal pad 410. The metal pad 410 has an oblong octagonal shape where the width, M_{wx2}, in the X-axis direction is less than the width, M_{wy2}, in the Y-axis direction.

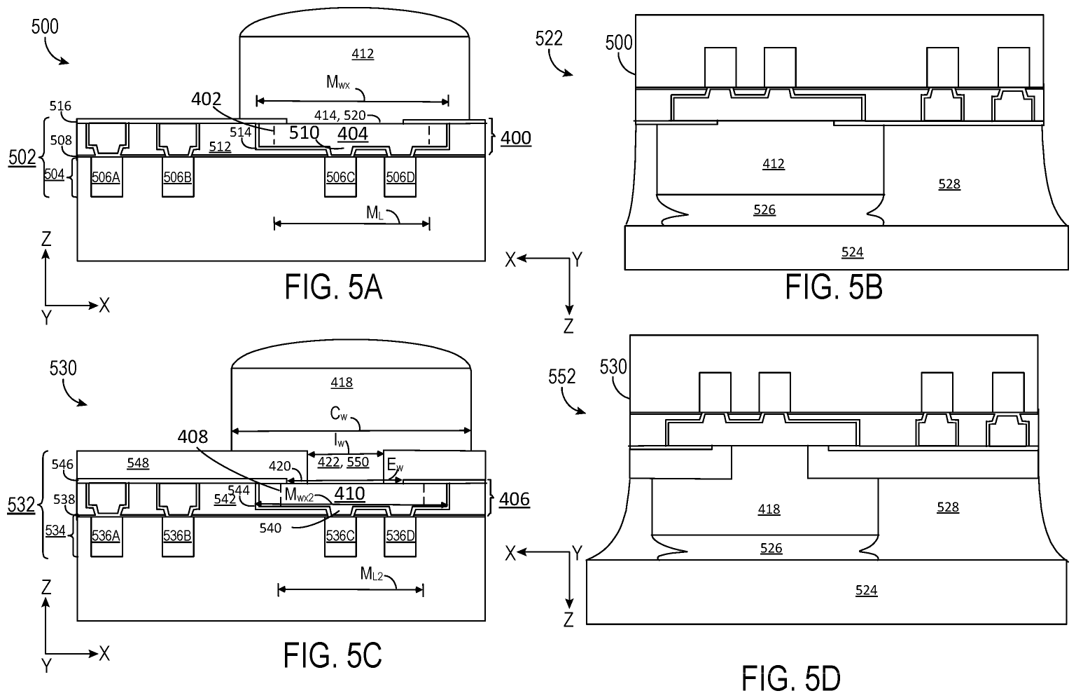

FIG. 4C is a top view of the exemplary DLD metallization layer 400 in FIG. 4A including a die interconnect 412 having a circular base. In this example, the die interconnect 412 is a core die interconnect carrying power and ground signals and is composed of copper. The DLD metallization layer 400 includes a passivation layer (not shown) and an optional polymer dielectric layer (not shown) such as a polyimide layer. The passivation layer and the optional polymer dielectric layer will be discussed in connection with FIG. 5C. A passivation opening 414 and an optional polymer dielectric opening 416 enable direct coupling between the die interconnect 412 and the metal pad 404. Generally, the passivation opening 414 defines a bump landing area for a die interconnect. In this example, the optional polymer dielectric opening 416 defines the bump landing area for the die interconnect 412. The width of the metal line, M_{L}, can be in a range between 35 μm and 80 μm, and preferably 48 μm. The diameter, C, of the die interconnect 412 can be in a range between 30 μm and 75 μm. The distance, D, between the periphery of the passivation opening 414 and the edge of the metal line 402 in the X-axis direction can be in a range between 1 μm and 15 μm, and preferably 2 μm. The diameter, E, of the passivation opening 414 can be in a range between 20 μm and 70 μm, and preferably 42 μm.

The distance, F, in the X-axis direction between the periphery of the passivation opening 414 and the periphery of the die interconnect 412 is in a range between 5 μm and 30 μm, and preferably 16 μm. When an optional polymer dielectric opening is deployed, the distance, G, in the X-axis direction between the periphery of the optional polymer dielectric opening 416 and the periphery of the passivation opening 414 is preferably around 2 μm. The diameter, I, of the polymer dielectric opening 416 can be in a range between 10 μm and 50 μm, and preferably 32 μm. The bump landing area defined by the polymer dielectric opening 416 can thus be in the range between 150 μm² and 3000 μm², preferably 803.84 μm².

FIG. 4D is a top view of the exemplary DLD metallization layer 406 in FIG. 4B including a die interconnect 418 having an oblong base. In this example, the die interconnect 418 is an input/output (I/O) die interconnect carrying information signals and is composed of copper. The DLD metallization layer 406 includes a passivation layer (not shown) and an optional polymer dielectric layer (not shown) such as a polyimide layer. The passivation layer and the optional polymer dielectric layer will be discussed in connection with FIG. 5C. A passivation opening 420 and an optional polymer dielectric opening 422 enable direct coupling between the die interconnect 418 and the metal pad 410. Generally, the passivation opening 420 defines a bump landing area for a die interconnect. In this example, the optional polymer dielectric opening 422 defines the bump landing area for the die interconnect 418. The width of the metal line, M_{L2}, can be in a range between 10 μm and 75 μm, and preferably 32 μm. The diameter, C_{w}, in the X-axis direction of the die interconnect 418 can be in a range between 35 μm and 45 μm. The diameter, C_{L}, in the Y-axis direction of the die interconnect 418 can be in a range between 65 μm and 75 μm. The distance, D_{L}, between the periphery of the passivation opening 420 and the edge of metal line 408 in the X-axis direction can be in a range between 1 μm and 15 μm, and preferably 2 μm. The diameter, E_{w}, in the X-axis direction of the passivation opening 420 can be in a range between 20 μm and 70 μm. The diameter, E_{L}, in the Y-axis direction of the passivation opening 420 can be in a range between 20 μm and 70 μm. The preferable diameters E_{w} and E_{L} are 25 μm and 35 μm, respectively.

The distance, F₁, in the X-axis direction between the periphery of the passivation opening 420 and the periphery of the die interconnect 418 is in a range between 5 μm and 30 μm. The distance, F₂, in the Y-axis direction between the periphery of the passivation opening 420 and the periphery of the die interconnect 418 is in a range between 5 μm and 30 μm. The preferable combination of distance F₁ and distance F₂ is 5 μm and 15 μm, respectively. When an optional polymer dielectric opening is deployed, the distance, G₁, in the X-axis direction between the periphery of the optional polymer opening 422 and the periphery of the passivation opening 420 is in a range between 2 μm and 30 μm. When an optional polymer dielectric opening is deployed, the distance, G₂, in the Y-axis direction between the periphery of the optional polymer opening 422 and the periphery of the passivation opening 420 is in a range between 2 μm and 30 μm. The preferable combination of distance G₁ and distance G₂ is 5 μm and 5 μm, respectively. The diameter, I_{w}, in the X-axis direction of the polymer dielectric opening 422 can be in a range between 10 μm and 20 μm. The diameter, I_{L}, in the Y-axis direction of the polymer dielectric opening 422 can be in a range between 20 μm and 30 μm. The preferable diameters I_{w} and I_{L} are 25 μm and 25 μm, respectively. The bump landing area defined by the polymer dielectric opening 422 can thus be in the range between 150 μm² and 3000 μm², preferably around 326.2 μm².

Dies can be deployed to have various DLD metallization structures. FIGS. 5A-5D address exemplary embodiments of various DLD metallization structures. Each die depicted in FIGS. 5A-5D includes a FEOL structure 306 and a BEOL structure 304. For simplicity, FIGS. 5A-5D focus on the DLD metallization structures and, thus, do not depict the FEOL structure 306 and the BEOL structure 304 as they are shown in FIG. 3. Common elements between the die 302 in FIG. 3 and the dies in FIGS. 5A-5D are shown with common element numbers. Common elements between metallization layers 400 and 406 in FIGS. 4A-4D and the metallization layers in FIGS. 5A-5D are shown with common element numbers.

FIG. 5A is a side view of an exemplary embodiment of a die 500, such as the die 302 in FIG. 3 focusing on an exemplary DLD metallization layer along cut line B₁-B₁ in the DLD metallization layer 400 of FIG. 4C which includes the metal line 402 and the metal pad 404 having a width greater than the width of the metal line 402 for improved signal path conductivity between the die interconnect and the metal pad. The die 500 includes a DLD metallization structure 502. The DLD metallization structure 502 includes an outer metallization layer 504 extending in the first, horizontal direction (X-, Y-axes direction), the outer metallization layer 504 comprising metal interconnects 506A-506D. The DLD metallization structure 502 also includes a passivation layer 508 extending in the first, horizontal direction (X-, Y-axes direction) adjacent in the second, vertical direction (Z-axis direction) to the outer metallization layer 504 and a via 510. The DLD metallization layer 400 extends in the first direction and is adjacent to the passivation layer 508. The DLD metallization layer 400 comprises the metal line 402 extending in the first, horizontal direction (X-, Y-axes direction). The metal line 402 has a width M_{L} in the third, horizontal direction (X-axis direction) orthogonal to the second direction. The DLD metallization layer 400 also comprises the metal pad 404 disposed in the metal line 402 wherein the metal pad 404 has a width M_{wx} in the third direction which is greater than the width M_{L}. The DLD metallization layer 400 includes a dielectric layer 512 and a barrier/seed layer 514 between the metal pad 404 and the dielectric layer 512. The DLD metallization layer 400 includes a passivation layer 516. The passivation layer 516 has an opening 414 which defines a via 520. The via 520 couples the die interconnect 412 to the metal pad 404. The die 500 does not include a polymer dielectric layer adjacent to the passivation layer 516. A bump landing area is defined by the area of the metal pad 404 enclosed by the opening 414. The metal pad 404 has a uniform hexagon shape as shown in FIG. 4C. In other embodiments, the metal pad 404 may have the shape of an oblong hexagon as shown in FIG. 4B. Also, the die interconnect 412 has a circular base as shown in FIG. 4C. In other embodiments, die interconnect 412 may have an oblong shape as shown in FIG. 4D.

FIG. 5B is a side view of an exemplary IC package 522 including the die 500 in FIG. 5A rotated 180° and assembled to a substrate 524. The IC package 522 includes the die interconnect 412 soldered to the substrate 524 through a solder 526. The IC package 522 includes an underfill material 528 to further insulate metal interconnects in the DLD metallization layer 400 and insulate the die interconnect 412 from other die interconnects.

FIG. 5C is a side view of an exemplary embodiment of a die 530, such as the die 302 in FIG. 3 focusing on an exemplary DLD metallization layer along cut line C₁-C₁ in the DLD metallization layer 406 of FIG. 4D which includes the metal line 408 and the metal pad 410 having a width greater than the width of the metal line 408 for improved signal path conductivity between the die interconnect 418 and the metal pad 410. The die 530 includes a DLD metallization structure 532. The DLD metallization structure 532 includes an outer metallization layer 534 extending in the first direction, the outer metallization layer 534 comprising metal interconnects 536A-536D. The DLD metallization structure 532 also includes a passivation layer 538 extending in the first, horizontal direction (X-, Y-axes direction) adjacent in a second, vertical direction (Z-axis direction) to the outer metallization layer 534 and a via 540. The DLD metallization layer 406 extends in the first direction and is adjacent to the passivation layer 538. The DLD metallization layer 406 comprises the metal line 408 extending in the first, horizontal direction (X-, Y-axes direction). The metal line 408 has a width M_{L2} in the third, horizontal direction (X-axis direction) orthogonal to the second direction. The DLD metallization layer 406 also comprises the metal pad 410 disposed in the metal line 408 wherein the metal pad 410 has a width M_{wx2} in the third direction which is greater than the width M_{L2}. The DLD metallization layer 406 includes a dielectric layer 542 and a barrier/seed layer 544 between the metal pad 410 and the dielectric layer 542. The DLD metallization structure 532 includes a passivation layer 546 and an optional polymer dielectric layer 548 adjacent to the passivation layer 546. The DLD metallization layer 406 includes the passivation layer 546 adjacent to the dielectric layer 542. The polymer dielectric layer 548 has the polymer dielectric opening 422 which defines a via 550. The via 550 couples the die interconnect 418 to the metal pad 410. A bump landing area is defined by the area of the metal pad 410 enclosed by the polymer dielectric opening 422. The metal pad 410 has an oblong hexagon shape as shown in FIG. 4D. In other embodiments, the metal pad 410 may have the shape of a uniform hexagon as shown in FIG. 4A. Also, the die interconnect 418 has an oblong base as shown in FIG. 4D. In other embodiments, the die interconnect 418 may have a circular shape as shown in FIG. 4C.

FIG. 5D is a side view of an exemplary IC package 552 including the die 530 in FIG. 5C rotated 180° and assembled to a substrate 524. The IC package 552 includes the die interconnect 418 soldered to the substrate 524 through a solder 526. The IC package 552 includes an underfill material 528 to further insulate metal interconnects in the DLD metallization layer 406 and insulate the die interconnect 418 from other die interconnects.

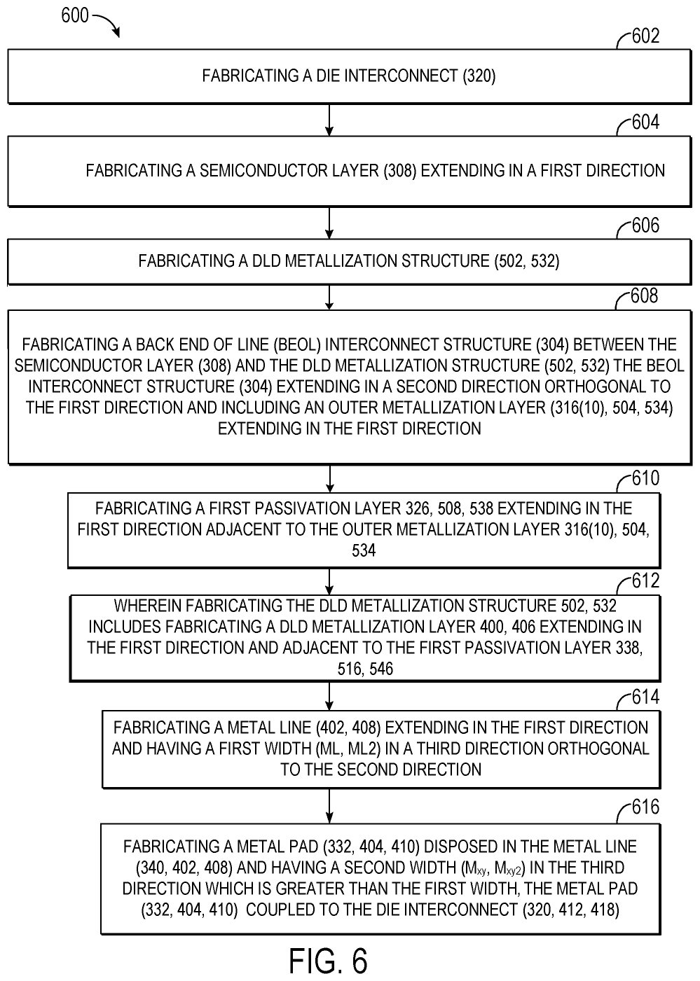

A die including a die interconnect and a DLD metallization layer including a metal line and a metal pad having a width greater than the width of the metal line for improved signal path conductivity between the die interconnect and the metal pad, including, but not limited to, the exemplary DLD metallization layers in FIGS. 3 and FIGS. 5A-5D and deployed in the related IC package 200 in FIG. 2 can be fabricated by different fabrication processes. FIG. 6 is a flowchart illustrating an exemplary fabrication process 600 of fabricating a die including a die interconnect and a DLD metallization layer including a metal line and a metal pad having a width greater than the width of the metal line for improved signal path conductivity between the die interconnect and the metal pad, including, but not limited to, the exemplary DLD metallization layers in FIGS. 3 and FIGS. 5A-5D.

In this regard, a first exemplary step for fabricating a die with an exemplary DLD metallization structure formed in the die in the fabrication process 600 of FIG. 6 can include fabricating a die interconnect 320, 412, 418 (block 602 in FIG. 6). The next step in the fabrication process 600 can include fabricating a semiconductor layer 308 extending in a first direction (block 604 in FIG. 6). The next step in the fabrication process 600 can include fabricating a DLD metallization structure 502, 532 (block 606 in FIG. 6). The next step in the fabrication process can include fabricating a BEOL interconnect structure 304 between the semiconductor layer 308 and the DLD metallization structure 502, 532, the BEOL interconnect structure 304 extending in a second direction orthogonal to the first direction and including an outer metallization layer 316(10), 204, 534 extending in the first direction (block 608 in FIG. 6). The step of fabricating the DLD metallization structure 502, 532 further comprises blocks 610-616. The next step of fabricating the DLD metallization structure 502, 532 can include fabricating a first passivation layer 326, 508, 538 extending in the first direction adjacent to the outer metallization layer 316(10), 504, 534 (block 610 in FIG. 6). The next step of fabricating the DLD metallization structure 502, 532 can include fabricating a DLD metallization layer 400, 406 extending in the first direction and adjacent to the first passivation layer 326, 508, 538 (block 612 in FIG. 6). The step of fabricating the DLD metallization layer 400, 406 further comprises blocks 614-616. The next step of fabricating the DLD metallization layer 400, 406 can include fabricating a metal line 340, 402, 408 extending in the first direction and having a first width in M_{L}, M_{L2} in a third direction orthogonal to the second direction (block 614 in FIG. 6). The next step of fabricating the DLD metallization layer 400, 406 can include fabricating a metal pad 332, 404, 410 disposed in the metal line 340, 402, 408 and having a second width M_{xy}, M_{xy2} in the third direction which is greater than the first width, the metal pad 332, 404, 410 coupled to the die interconnect 320, 412, 418 (block 616 in FIG. 6).

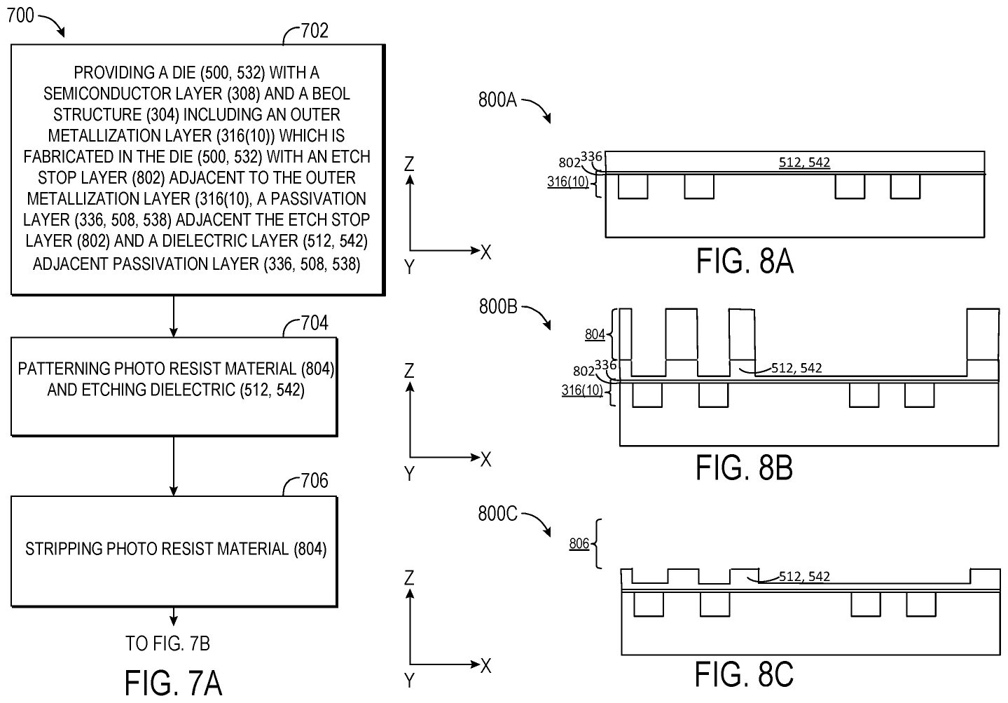

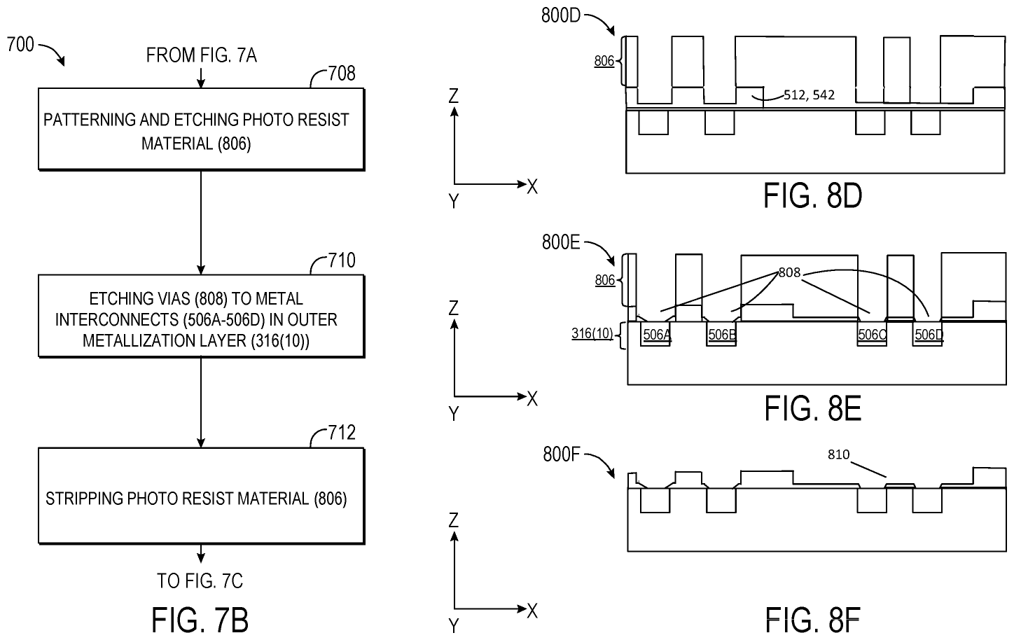

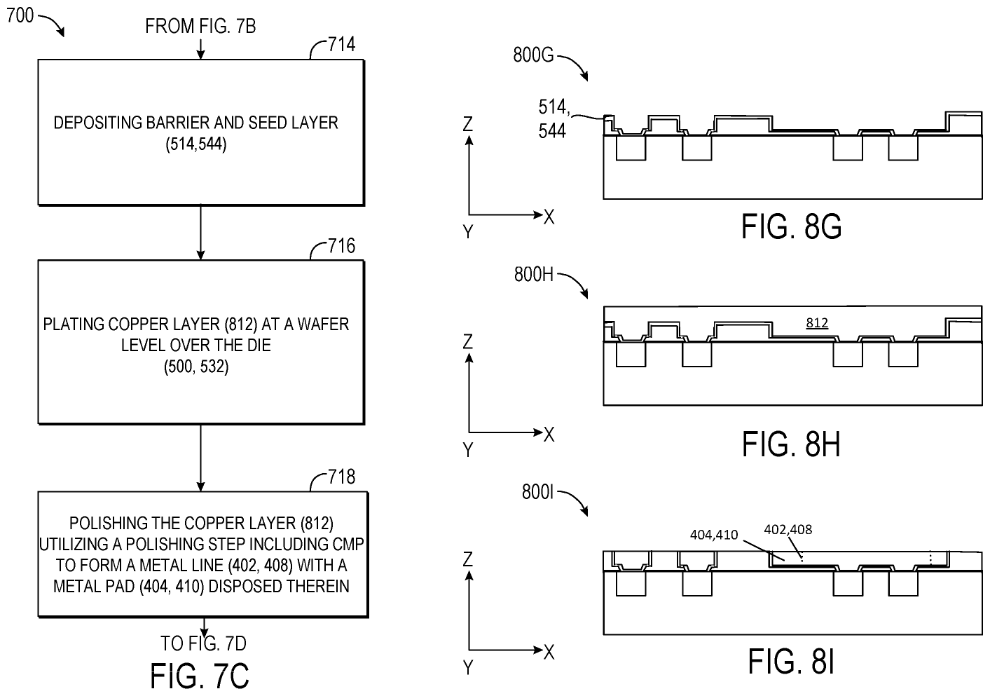

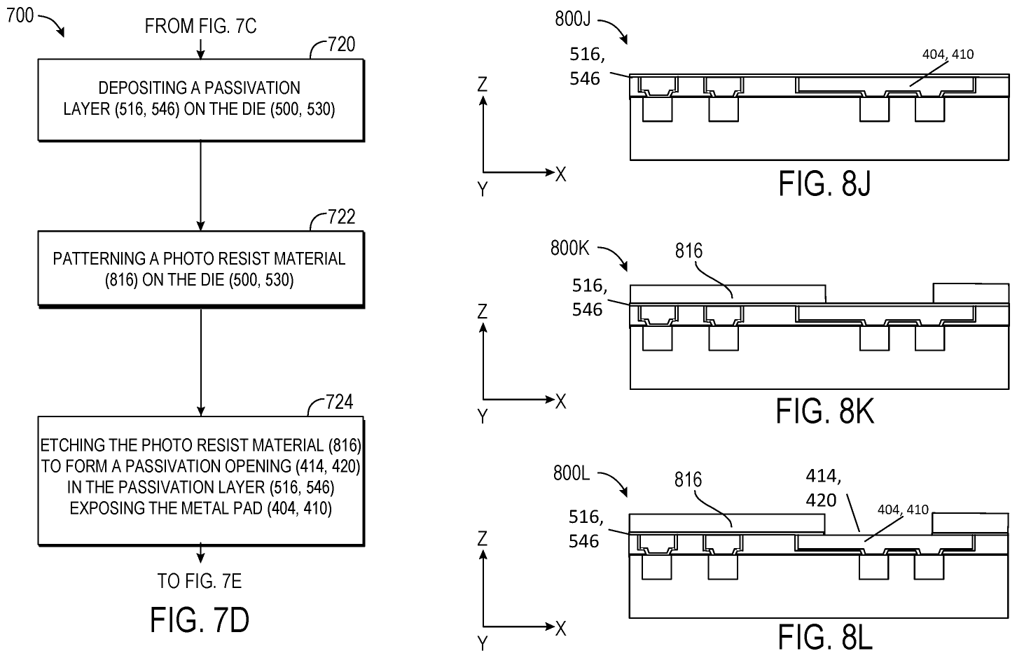

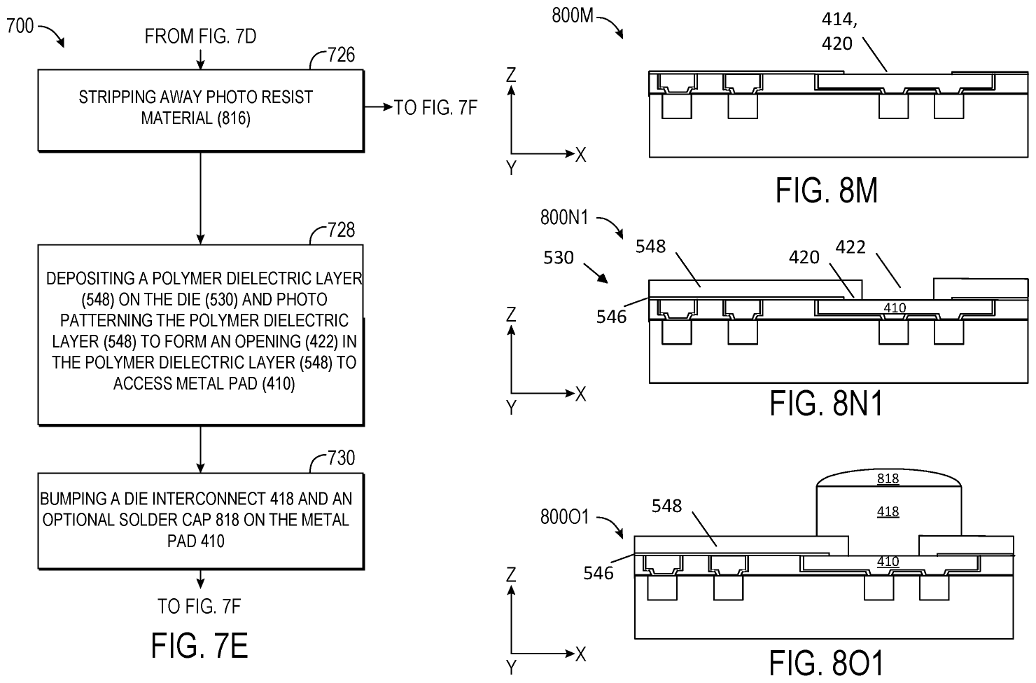

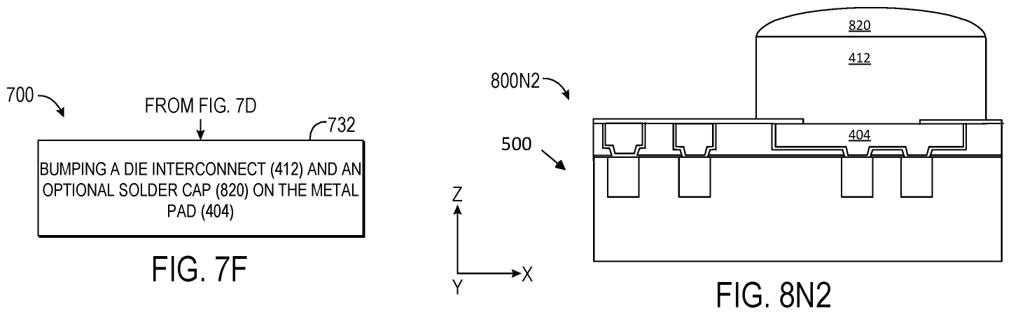

Other fabrication processes can also be employed to fabricate a die including a die interconnect and a DLD metallization layer including a metal line and a metal pad having a width greater than the width of the metal line for improved signal path conductivity between the die interconnect and the metal pad, including, but not limited to, the exemplary DLD metallization layers in FIGS. 3 and FIGS. 5A-5D and in the related IC package 200 in FIG. 2. In this regard, FIGS. 7A-7F is a flowchart illustrating another exemplary fabrication process 700 of fabricating a die including a die interconnect and a DLD metallization layer including a metal line and a metal pad having a width greater than the width of the metal line for improved signal path conductivity between the die interconnect and the metal pad, including, but not limited to, the exemplary DLD metallization layers in FIGS. 3 and FIGS. 5A-5D. FIGS. 8A-8N2 are exemplary fabrication stages 800A-800N2 during fabrication of the die according to the fabrication process 700 in FIGS. 7A-7F. The fabrication process 700 as shown in the fabrication stages 800A-800N2 in FIGS. 8A-8N2 are in reference to the cross-sectional side view of a die and, thus, will be discussed with reference to the dies 500, 530 in FIGS. 5A and 5C which are deployed, such as the die 208(1), in the related IC package 200 in FIG. 2 and/or respective IC packages 522, 552, respectively. In particular blocks 702-730 relate to the die 530 and blocks 702-726 and 732 relate to the die 500. For simplicity, the fabrication process 700 will be focused on the DLD metallization structure 502, 532 fabricated therein.

In this regard, as shown in fabrication stage 800A in FIG. 8A, an exemplary step in the fabrication process 700 is providing a die 500, 530 with a semiconductor layer (not visible) and a BEOL structure 304 including an outer metallization layer 316(10) which is fabricated in the die 500, 530 with an etch stop layer 802 adjacent to the outer metallization layer 316(10), a passivation layer 326, 508, 538 adjacent the etch stop layer 802, and a dielectric layer 512, 542 adjacent the passivation layer 326, 508, 538 (block 702 in FIG. 7A). Although not shown in the fabrication stages for simplicity, the fabrication stages address a wafer level fabrication process where the die 500, 530 is one of many dies disposed in a wafer. As shown in fabrication stage 800B in FIG. 8B, a next step in the fabrication process 700 can include patterning a photo resist material 804 and etching the dielectric layer 512, 542 (block 704 in FIG. 7A). As shown in fabrication stage 800C in FIG. 8C, a next step in the fabrication process 700 can include stripping the photo resist material 804 (block 706 in FIG. 7A). In this step, the etched out portion of the dielectric layer 512, 542 and the stripped photo resist material 804 creates forms for metal lines and a metal pads disposed therein such as form 810 for metal lines 402, 408 and metal pads 404, 410 disposed in the metal lines 402, 408, respectively, wherein the widths of the metal pads 404, 410 are greater than the widths of the metal lines 402, 408.

As shown in fabrication stage 800D in FIG. 8D, a next step in the fabrication process 700 can include and patterning and etching a photo resist material 806 (block 708 in FIG. 7B). As shown in fabrication stage 800E in FIG. 8E, a next step in the fabrication process 700 can include etching vias 808 to metal interconnects 506A-506D in the outer metallization layer 316(10) (block 710 in FIG. 7B). Please note that for simplicity the passivation layer 326 is no longer delineated.

As shown in fabrication stage 800F in FIG. 8F, a next step in the fabrication process 700 can include stripping the photo resist material 806 (block 712 in FIG. 7B).

As shown in fabrication stage 800G in FIG. 8G, a next step in the fabrication process 700 can include depositing a barrier/seed layer 514, 544 (block 714 in FIG. 7C). As shown in fabrication stage 800H in FIG. 8H, a next step in the fabrication process 700 can include plating a copper layer 812 at a wafer level over the die 500, 530 (block 716 in FIG. 7C). As shown in fabrication stage 800I in FIG. 8I, a next step in the fabrication process 700 can include polishing the copper layer 812 utilizing a polishing step including CMP to form a metal line 402, 408 with a metal pad 404, 410 disposed therein (block 718 in FIG. 7C).

As shown in fabrication stage 800J in FIG. 8J, a next step in the fabrication process 700 can include depositing a passivation layer 516, 546 on the die 500, 530 (block 720 in FIG. 7D). As shown in fabrication stage 800K in FIG. 8K, a next step in the fabrication process 700 can include patterning a photo resist material 816 on the die 500, 530 (block 722 in FIG. 7D). As shown in fabrication stage 800L in FIG. 8L, a next step in the fabrication process 700 can include etching the photo resist material 816 to form a passivation opening 414, 420 in the passivation layer 516, 546 exposing the metal pad 404, 410 (block 724 in FIG. 7D).

As shown in fabrication stage 800M in FIG. 8M, a next step in the fabrication process 700 can include stripping away the photo resist material 816 (block 726 in FIG. 7E). If the die 500 is being fabricated, the process 700 proceeds to block 732 in FIG. 7F. Continuing with fabricating the die 530, the process 700 proceeds to block 728 in FIG. 7E As shown in fabrication stage 800N1 in FIG. 8N1, a next step in the fabrication process 700 can include depositing a polymer dielectric layer 548 (e.g. polyimide material) on the die 530, and photo patterning the polymer dielectric layer 548 to form an opening 422 in the polymer dielectric layer 548 to access the metal pad 410 (block 728 in FIG. 7E). This step of the process 700 can be tailored to etch the polymer dielectric layer 548 so that the opening 422 in the polymer dielectric layer 548 encloses the same area of the metal pad 410 as the opening 420 in the passivation layer 546.

As shown in fabrication stage 80001 in FIG. 801, a next step in the fabrication process 700 can include bumping a die interconnect 418 and an optional solder cap 818 on the metal pad 410 (block 730 in FIG. 7E).

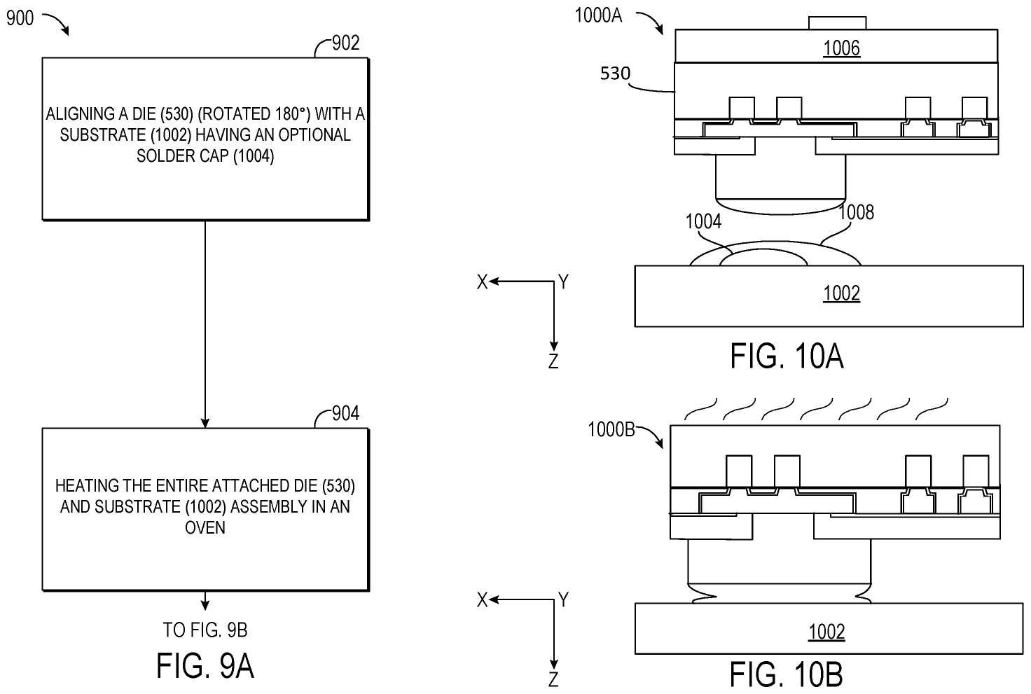

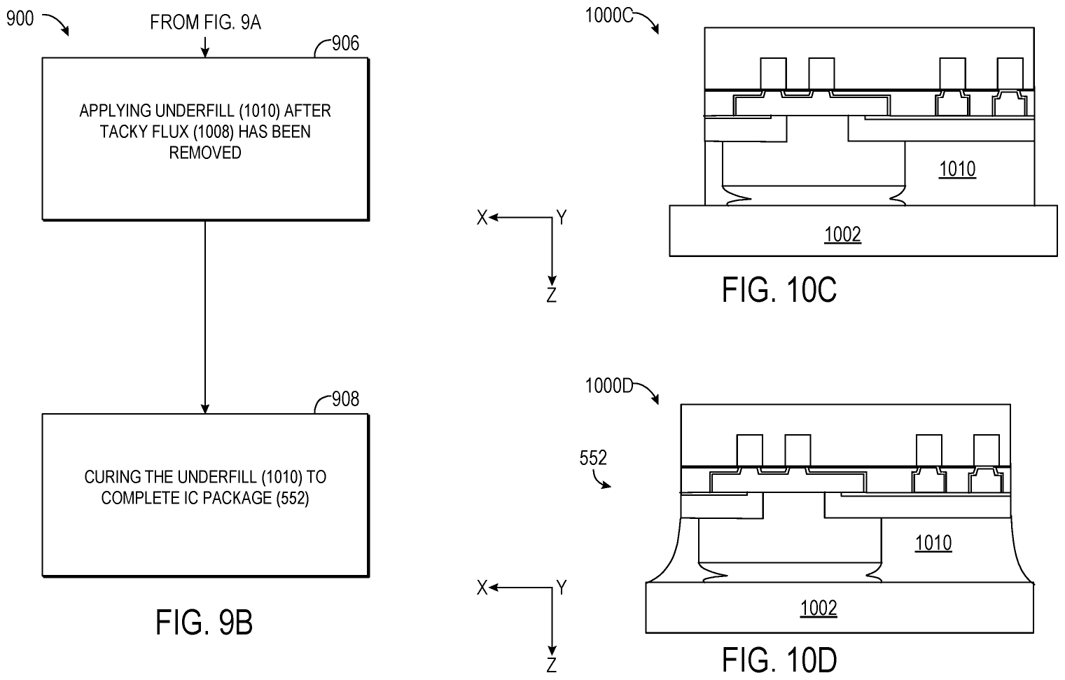

Returning to block 726 in FIG. 7E, the process 700 proceeds to block 732 of FIG. 7F to continue fabrication of the die 500. As shown in fabrication stage 800N2 in FIG. 8N2, a next step in the fabrication process 700 can include bumping a die interconnect 412 and an optional solder cap 820 on the metal pad 404 without depositing a polymer dielectric layer (block 732 in FIG. 7F). At the end of the wafer level fabrication process 700, the dies disposed on a wafer including the dies 500, 530 are singulated from the wafer and sent to an assembly process such as the assembly processes that will be discussed in connection with FIGS. 9-12.

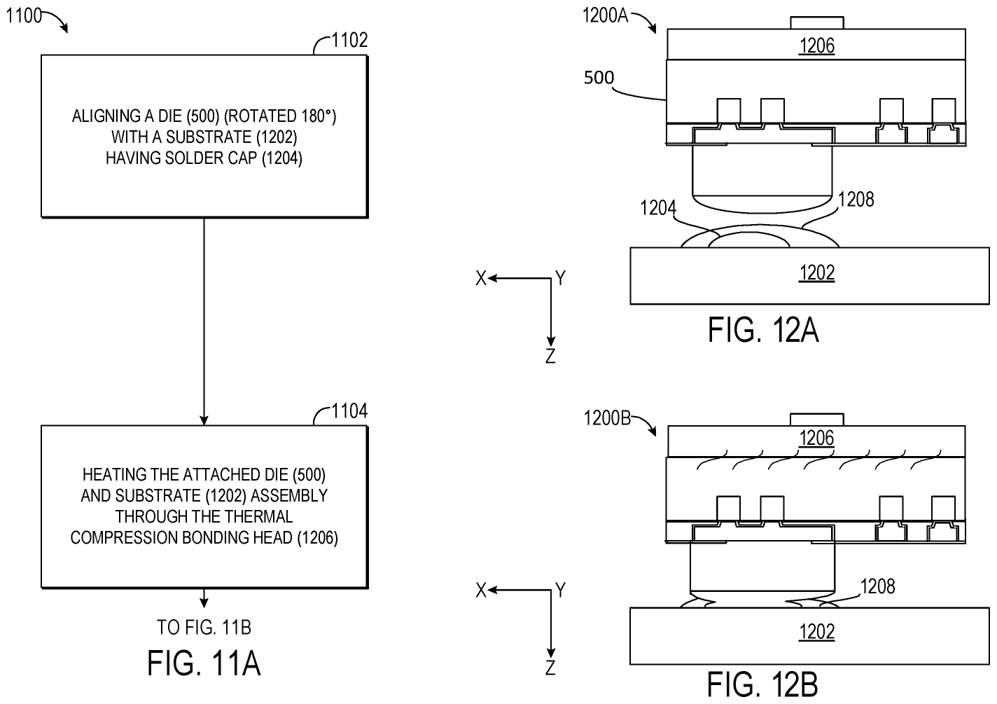

An IC package including a die including a die interconnect and a DLD metallization layer including a metal line and a metal pad having a width greater than the width of the metal line for improved signal path conductivity between the die interconnect and the metal pad, including, but not limited to the exemplary 3DIC package 200 in FIG. 2 and the dies 500 and 530 in FIGS. 5A-5D in the related IC package 200 in FIG. 2 or the IC package 522 and 552, can be assembled by different assembly processes. FIGS. 9A-9B is a flowchart illustrating an exemplary mass reflow assembly process 900 of assembling a die to a substrate, the die including a die interconnect and a DLD metallization layer including a metal line and a metal pad having a width greater than the width of the metal line for improved signal path conductivity between the die interconnect and the metal pad, including, but not limited to, the exemplary DLD metallization layers in FIGS. 3 and 5A-5D. FIGS. 10A-10D are exemplary assembly stages for assembling the die to the substrate according to the assembly process 900 in FIGS. 9A-9B. The assembly process 900 may be applied to dies with a polymer dielectric layer such as the polymer dielectric layer 548 in the die 530 in FIGS. 5C and 801 and will be described in relation to the die 530.

In this regard, as shown in assembly stage 1000A in FIG. 10A, an exemplary step in the assembly process 900 can include aligning the die 530 (rotated 180°) with a substrate 1002 having an optional solder cap 1004 (block 902 in FIG. 9A). The die 530 is placed on a carrier 1006 to align the die 530 with the substrate 1002. The bump landing pad 1004 is covered with a tacky flux 1008. The tacky flux 1008 facilitates placing the die 530 on the substrate 1002 with minor force.

As shown in assembly stage 1000B in FIG. 10B, a next step in the assembly process 900 can include heating the entire attached die 530 and substrate 1002 assembly in an oven (block 904 in FIG. 9A). As shown in assembly stage 1000C in FIG. 10C, a next step in the assembly process 900 can include applying an underfill 1010 after the tacky flux 1008 has been removed (block 906 in FIG. 9B). As shown in assembly stage 1000D in FIG. 10D, a next step in the assembly process 900 can include curing the underfill 1010 to complete the IC package 552 (block 908 in FIG. 9B).

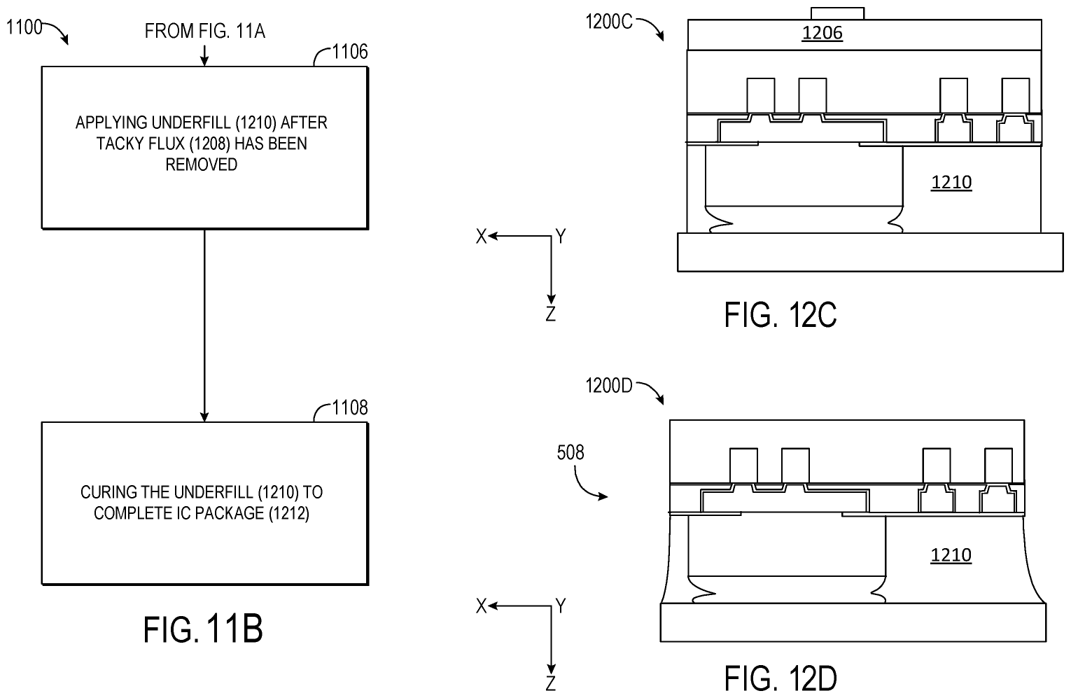

FIGS. 11A-11B is a flowchart illustrating an exemplary thermal compression assembly process 1100 of assembling a die to a substrate, the die including a die interconnect and a DLD metallization layer including a metal line and a metal pad having a width greater than the width of the metal line for improved signal path conductivity between the die interconnect and the metal pad, including, but not limited to, the exemplary DLD metallization layer in FIGS. 3 and 5A-5D. The assembly process 1100 may be applied to dies with or without a polymer dielectric layer such as the polymer dielectric layer 548 and will be described in relation to the die 500. FIGS. 12A-12D are exemplary assembly stages during assembling the die to the substrate according to the assembly process in FIGS. 11A-11B. The assembly process 1100 may be applied to the dies 500 and 530 but will be described in relation to the die 500.

In this regard, as shown in assembly stage 1200A in FIG. 12A, an exemplary step in the assembly process 1100 can include aligning the die 500 (rotated 180°) with a substrate 1202 having a solder cap 1204 (block 1102 in FIG. 11A). The die 500 is placed on a thermal compression bonding head 1206 to align the die 500 with the substrate 1202. The solder cap 1204 is covered with a tacky flux 1208. The tacky flux 1208 facilitates placing the die 500 on the substrate 1202 with minor force. As shown in assembly stage 1200B in FIG. 12B, a next step in the assembly process 1100 can include heating the attached die 500 and substrate 1202 assembly through the thermal compression bonding head 1206 (block 1104 in FIG. 11A). As shown in assembly stage 1200C in FIG. 12C, a next step in the assembly process 1100 can include applying an underfill 1210 after the tacky flux 1208 has been removed. (block 1106 in FIG. 11B). As shown in assembly stage 1200D in FIG. 12D, a next step in the assembly process 1100 can include curing the underfill 1210 to complete the IC package 522. (block 1108 in FIG. 11B).

Electronic devices that include an IC package, wherein the IC package includes a die attached to a substrate, the die including a DLD metallization structure including a metal pad and a shorter via coupling the metal pad to a metal interconnect in the die for improved signal path conductivity, including, but not limited to, the exemplary DLD metallization structures in FIGS. 3 and 5A-5D in the related IC package 200 in FIG. 2, and that can be fabricated according to, but not limited to, the exemplary fabrication processes in FIGS. 6 and 7A-7F, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, and a multicopter.

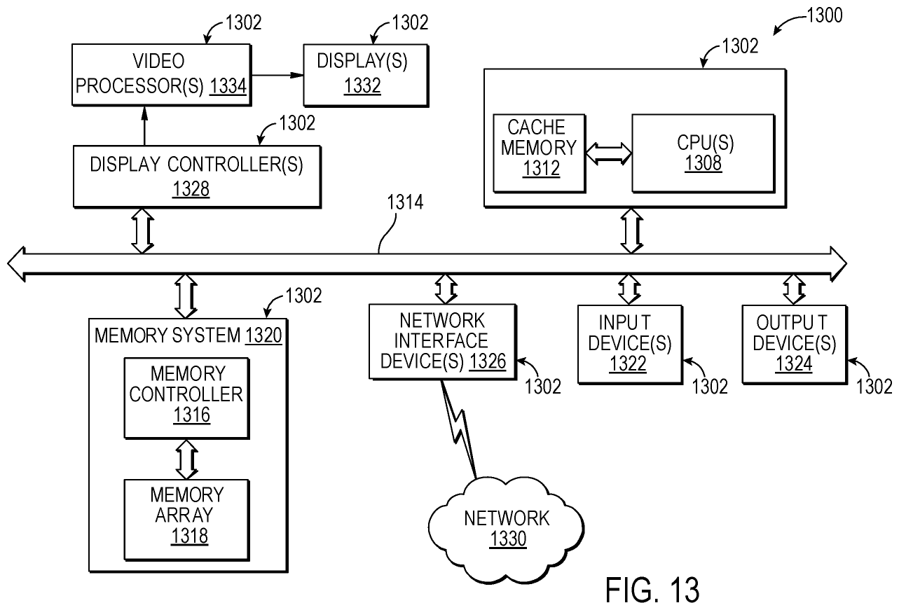

In this regard, FIG. 13 is a block diagram of an exemplary processor-based system 1300 that can include components deployed in an IC package employing a die(s) coupled to a package substrate, wherein the die(s) can include a die interconnect and a DLD metallization layer including a metal line and a metal pad having a width greater than the width of the metal line for improved signal path conductivity between the die interconnect and the metal pad, including, but not limited to, the exemplary dies in FIGS. 3 and 5A-5D, according to the exemplary fabrication processes in FIG. 6 and FIGS. 7A-7F, and according to exemplary assembly processes in FIGS. 9A-9B and 11A-11B, and according to any exemplary aspects disclosed herein. In this example, the processor-based system 1300 may be formed as an IC package 1302 such as the IC package 200 in FIG. 2. The processor-based system 1300 includes a central processing unit (CPU) 1308 that includes one or more processors 1310, which may also be referred to as CPU cores or processor cores. The CPU 1308 may have cache memory 1312 coupled to the CPU 1308 for rapid access to temporarily stored data. The CPU 1308 is coupled to a system bus 1314 and can intercouple master and slave devices included in the processor-based system 1300. As is well known, the CPU 1308 communicates with these other devices by exchanging address, control, and data information over the system bus 1314. For example, the CPU 1308 can communicate bus transaction requests to a memory controller 1316, as an example of a slave device. Although not illustrated in FIG. 13, multiple system buses 1314 could be provided, wherein each system bus 1314 constitutes a different fabric.

Other master and slave devices can be connected to the system bus 1314. As illustrated in FIG. 13, these devices can include a memory system 1320 that includes the memory controller 1316 and a memory array(s) 1318, one or more input devices 1322, one or more output devices 1324, one or more network interface devices 1326, and one or more display controllers 1328, as examples. Each of the memory system(s) 1320, the one or more input devices 1322, the one or more output devices 1324, the one or more network interface devices 1326, and the one or more display controllers 1328 can be provided in the same or different electronic devices. The input device(s) 1322 can include any type of input device, including, but not limited to, input keys, switches, voice processors, etc. The output device(s) 1324 can include any type of output device, including, but not limited to, audio, video, other visual indicators, etc. The network interface device(s) 1326 can be any device configured to allow exchange of data to and from a network 1330. The network 1330 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1326 can be configured to support any type of communications protocol desired.

The CPU 1308 may also be configured to access the display controller(s) 1328 over the system bus 1314 to control information sent to one or more displays 1332. The display controller(s) 1328 sends information to the display(s) 1332 to be displayed via one or more video processors 1334, which process the information to be displayed into a format suitable for the display(s) 1332. The display controller(s) 1328 and video processor(s) 1334 can be included as ICs in the same or different electronic devices, and in the same or different electronic devices containing the CPU 1308, as an example. The display(s) 1332 can include any type of display, including, but not limited to, a cathode ray tube (CRT), a liquid crystal display (LCD), a plasma display, a light emitting diode (LED) display, etc.

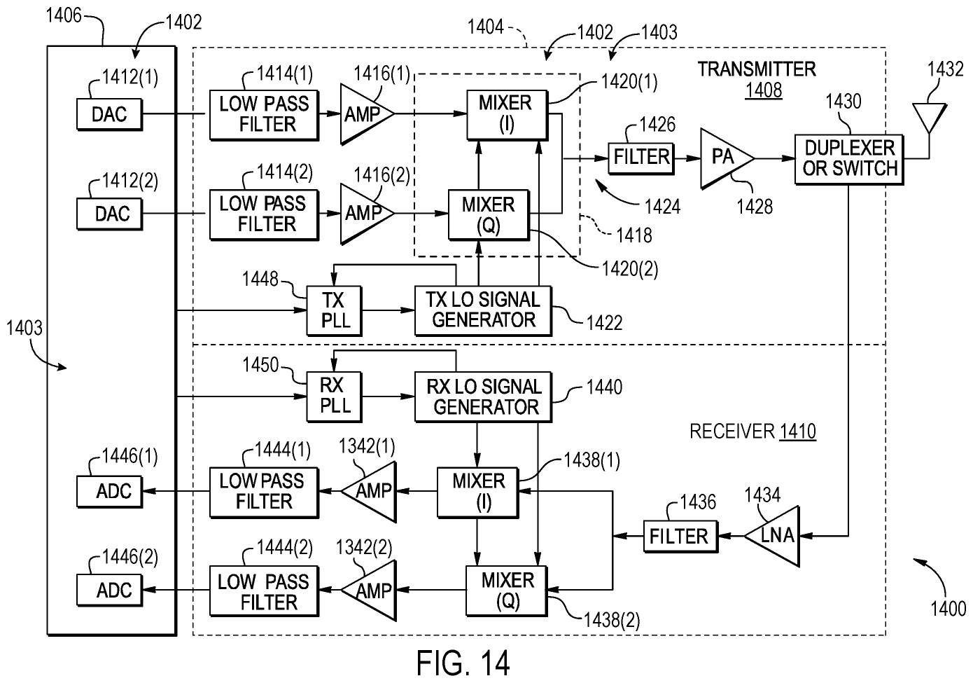

FIG. 14 is a block diagram of an exemplary wireless communications device that includes radio-frequency (RF) components deployed in an IC package, wherein the IC package includes a die including a die interconnect and a DLD metallization layer including a metal line and a metal pad having a width greater than the width of the metal line for improved signal path conductivity between the die interconnect and the metal pad, including, but not limited to, the exemplary dies in FIGS. 3 and 5A-5D, according to the exemplary fabrication processes in FIG. 6 and FIGS. 7A-7F, and according to exemplary assembly processes in FIGS. 9A-9B and 11A-11B, and according to any exemplary aspects disclosed herein. The wireless communications device 1400 may include or be provided in any of the above-referenced devices, as examples. As shown in FIG. 14, the wireless communications device 1400 includes a transceiver 1404 and a data processor 1406. The data processor 1406 may include a memory to store data and program codes. The transceiver 1404 includes a transmitter 1408 and a receiver 1410 that support bi-directional communications. In general, the wireless communications device 1400 may include any number of transmitters 1408 and/or receivers 1410 for any number of communication systems and frequency bands. All or a portion of the transceiver 1404 may be implemented on one or more analog ICs, RF ICs (RFICs), mixed-signal ICs, etc.

The transmitter 1408 or the receiver 1410 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 1410. In the direct-conversion architecture, a signal is frequency-converted between RF and baseband in one stage. The super-heterodyne and direct-conversion architectures may use different circuit blocks and/or have different requirements. In the wireless communications device 1400 in FIG. 14, the transmitter 1408 and the receiver 1410 are implemented with the direct-conversion architecture.

In the transmit path, the data processor 1406 processes data to be transmitted and provides I and Q analog output signals to the transmitter 1408. In the exemplary wireless communications device 1400, the data processor 1406 includes digital-to-analog converters (DACs) 1412(1), 1412(2) for converting digital signals generated by the data processor 1406 into the I and Q analog output signals (e.g., I and Q output currents) for further processing.

Within the transmitter 1408, lowpass filters 1414(1), 1414(2) filter the I and Q analog output signals, respectively, to remove undesired signals caused by the prior digital-to-analog conversion. Amplifiers (AMPs) 1416(1), 1416(2) amplify the signals from the lowpass filters 1414(1), 1414(2), respectively, and provide I and Q baseband signals. An upconverter 1318 upconverts the I and Q baseband signals with I and Q transmit (TX) local oscillator (LO) signals through mixers 1420(1), 1420(2) from a TX LO signal generator 1422 to provide an upconverted signal 1424. A filter 1426 filters the upconverted signal 1424 to remove undesired signals caused by the frequency up-conversion as well as noise in a receive frequency band. A power amplifier (PA) 1428 amplifies the upconverted signal 1424 from the filter 1426 to obtain the desired output power level and provides a transmit RF signal. The transmit RF signal is routed through a duplexer or switch 1430 and transmitted via an antenna 1432.

In the receive path, the antenna 1432 receives signals transmitted by base stations and provides a received RF signal, which is routed through the duplexer or switch 1430 and provided to a low noise amplifier (LNA) 1434. The duplexer or switch 1430 is designed to operate with a specific receive (RX)-to-TX duplexer frequency separation, such that RX signals are isolated from TX signals. The received RF signal is amplified by the LNA 1434 and filtered by a filter 1436 to obtain a desired RF input signal. Down-conversion mixers 1438(1), 1438(2) mix the output of the filter 1436 with I and Q RX LO signals (i.e., LO_I and LO_Q) from an RX LO signal generator 1440 to generate I and Q baseband signals. The I and Q baseband signals are amplified by AMPs 1442(1), 1442(2) and further filtered by lowpass filters 1444(1), 1444(2) to obtain I and Q analog input signals, which are provided to the data processor 1406. In this example, the data processor 1406 includes analog-to-digital converters (ADCs) 1446(1), 1446(2) for converting the analog input signals into digital signals to be further processed by the data processor 1406.

In the wireless communications device 1400 of FIG. 14, the TX LO signal generator 1422 generates the I and Q TX LO signals used for frequency up-conversion, while the RX LO signal generator 1440 generates the I and Q RX LO signals used for frequency down-conversion. Each LO signal is a periodic signal with a particular fundamental frequency. A TX phase-locked loop (PLL) circuit 1448 receives timing information from the data processor 1406 and generates a control signal used to adjust the frequency and/or phase of the TX LO signals from the TX LO signal generator 1422. Similarly, an RX PLL circuit 1450 receives timing information from the data processor 1406 and generates a control signal used to adjust the frequency and/or phase of the RX LO signals from the RX LO signal generator 1440.

Those of skill in the art will further appreciate that the various illustrative logical blocks, modules, circuits, and algorithms described in connection with the aspects disclosed herein may be implemented as electronic hardware, instructions stored in memory or in another computer readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. A semiconductor die (die), comprising:
a die interconnect;
a semiconductor layer extending in a first direction;
a die level distribution (DLD) metallization structure; and
a back end of line (BEOL) interconnect structure between the semiconductor layer and the DLD metallization structure, the BEOL interconnect structure extending in a second direction orthogonal to the first direction and including an outer metallization layer;
the DLD metallization structure comprising:
   the outer metallization layer extending in the first direction;
   a first passivation layer extending in the first direction adjacent to the outer metallization layer; and
   a DLD metallization layer extending in the first direction and adjacent to the first passivation layer, the DLD metallization layer comprising:
      a metal line extending in the first direction and having a first width in a third direction orthogonal to the second direction; and
      a metal pad disposed in the metal line and having a second width in the third direction which is greater than the first width, the metal pad coupled to the die interconnect.
         2. The semiconductor die of clause 1, wherein the die interconnect has a circular base having a third width extending in the third direction which is greater than the first width.
         3. The semiconductor die of clause 1, wherein the die interconnect has an oblong base having the third width extending in the third direction and having a fourth width extending in a fourth direction orthogonal to the third direction and is greater than the third width.
         4. The semiconductor die of clause 1 or 2, wherein the metal pad has a uniform octagonal shape.
         5. The semiconductor die of clause 1 or 3, wherein the metal pad has an oblong octagonal shape.
         6. The semiconductor die of any of clauses 1-5, wherein
the DLD metallization structure further comprises:
   a second passivation layer extending in the first direction adjacent to the DLD metallization layer, wherein the second passivation layer includes a first opening adjacent to the metal pad.
      7. The semiconductor die of clause 6, wherein
the DLD metallization structure further comprises:
   a polymer dielectric layer extending in the first direction adjacent to the second passivation layer, wherein the polymer dielectric layer includes a second opening adjacent to the first opening.
      8. The semiconductor die of clause 6 or 7, wherein the first opening has a first opening width of 25 micrometers (μm) and a length of 35 μm.
      9. The semiconductor die of clause 7 or 8, wherein the second opening has a second opening width in a first range between 10-20 micrometers (μm) and a length in a second range between 20-30 μm.
      10. The semiconductor die of any of clauses 7-9, wherein a distance between the first opening and the second opening is greater than or equal to 2 micrometers (μm) in the first direction.
      11. The semiconductor die of any of clauses 1-10 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; and a multicopter.
      12. A method of fabricating a semiconductor die (die) including a die interconnect and a metallization layer including a metal line and a metal pad having a width greater than a width of the metal line for improved signal path conductivity between the die interconnect and the metal pad, comprising:
fabricating the die interconnect;
fabricating a semiconductor layer extending in a first direction;
fabricating a die level distribution (DLD) metallization structure; and fabricating a back end of line (BEOL) interconnect structure between the semiconductor layer and the DLD metallization structure, the BEOL interconnect structure extending in a second direction orthogonal to the first direction and including an outer metallization layer extending in the first direction;
wherein fabricating the DLD metallization structure comprises:
   fabricating a first passivation layer extending in the first direction adjacent to the outer metallization layer; and
   fabricating a DLD metallization layer extending in the first direction and adjacent to the first passivation layer,
   wherein fabricating the DLD metallization layer comprises:
      fabricating the metal line extending in the first direction and having a first width in a third direction orthogonal to the second direction; and
      fabricating the metal pad disposed in the metal line and having a second width in the third direction which is greater than the first width, the metal pad coupled to the die interconnect.
         13. The method of clause 12, wherein the die interconnect has a circular base having a third width extending in the third direction which is greater than the first width.
         14. The method of clause 12 or 13, wherein the die interconnect has an oblong base having the third width extending in the third direction and having a fourth width extending in a fourth direction orthogonal to the third direction and is greater than the third width.
         15. The method of clause 12 or 13, wherein the metal pad has a uniform octagonal shape.
         16. The method of any of clauses 12-14, wherein the metal pad has an oblong octagonal shape.
         17. The method of any of clauses 12-16, wherein the DLD metallization structure further comprises:
a second passivation layer extending in the first direction adjacent to the DLD metallization layer, wherein the second passivation layer includes a first opening adjacent to the metal pad.
   18. The method of clause 17, wherein the DLD metallization structure further comprises:
a polymer dielectric layer extending in the first direction adjacent to the second passivation layer, wherein the polymer dielectric layer includes a second opening adjacent to the first opening.
   19. The method of clause 17 or 18, wherein the first opening has a first opening width of 25 micrometers (μm) and a length of 35 μm.
   20. The method of clause 18 or 19, wherein the second opening has a second opening width in a first range between 10-20 micrometers (μm) and a length in a second range between 20-30 μm.

What is claimed is:

1. A semiconductor die (die), comprising:
a die interconnect;
a semiconductor layer extending in a first direction;
a die level distribution (DLD) metallization structure; and
a back end of line (BEOL) interconnect structure between the semiconductor layer and the DLD metallization structure, the BEOL interconnect structure extending in a second direction orthogonal to the first direction and including an outer metallization layer;
the DLD metallization structure comprising:
the outer metallization layer extending in the first direction;
a first passivation layer extending in the first direction adjacent to the outer metallization layer; and
a DLD metallization layer extending in the first direction and adjacent to the first passivation layer, the DLD metallization layer comprising:
a metal line extending in the first direction and having a first width in a third direction orthogonal to the second direction; and
a metal pad disposed in the metal line and having a second width in the third direction which is greater than the first width, the metal pad coupled to the die interconnect.

2. The semiconductor die of claim 1, wherein the die interconnect has a circular base having a third width extending in the third direction which is greater than the first width.

3. The semiconductor die of claim 2, wherein the die interconnect has an oblong base having the third width extending in the third direction and having a fourth width extending in a fourth direction orthogonal to the third direction and is greater than the third width.

4. The semiconductor die of claim 1, wherein the metal pad has a uniform octagonal shape.

5. The semiconductor die of claim 1, wherein the metal pad has an oblong octagonal shape.

6. The semiconductor die of claim 1, wherein
the DLD metallization structure further comprises:
a second passivation layer extending in the first direction adjacent to the DLD metallization layer, wherein the second passivation layer includes a first opening adjacent to the metal pad.

7. The semiconductor die of claim 6, wherein
the DLD metallization structure further comprises:
a polymer dielectric layer extending in the first direction adjacent to the second passivation layer, wherein the polymer dielectric layer includes a second opening adjacent to the first opening.

8. The semiconductor die of claim 6, wherein the first opening has a first opening width of 25 micrometers (μm) and a length of 35 μm.

9. The semiconductor die of claim 7, wherein the second opening has a second opening width in a first range between 10-20 micrometers (μm) and a length in a second range between 20-30 μm.

10. The semiconductor die of claim 7, wherein a distance between the first opening and the second opening is greater than or equal to 2 micrometers (μm) in the first direction.

11. The semiconductor die of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; and a multicopter.

12. A method of fabricating a semiconductor die (die) including a die interconnect and a metallization layer including a metal line and a metal pad having a width greater than a width of the metal line for improved signal path conductivity between the die interconnect and the metal pad, comprising:
fabricating the die interconnect;
fabricating a semiconductor layer extending in a first direction;
fabricating a die level distribution (DLD) metallization structure; and
fabricating a back end of line (BEOL) interconnect structure between the semiconductor layer and the DLD metallization structure, the BEOL interconnect structure extending in a second direction orthogonal to the first direction and including an outer metallization layer extending in the first direction;
wherein fabricating the DLD metallization structure comprises:
fabricating a first passivation layer extending in the first direction adjacent to the outer metallization layer; and
fabricating a DLD metallization layer extending in the first direction and adjacent to the first passivation layer,
wherein fabricating the DLD metallization layer comprises:
fabricating the metal line extending in the first direction and having a first width in a third direction orthogonal to the second direction; and
fabricating the metal pad disposed in the metal line and having a second width in the third direction which is greater than the first width, the metal pad coupled to the die interconnect.

13. The method of claim 12, wherein the die interconnect has a circular base having a third width extending in the third direction which is greater than the first width.

14. The method of claim 13, wherein the die interconnect has an oblong base having the third width extending in the third direction and having a fourth width extending in a fourth direction orthogonal to the third direction and is greater than the third width.

15. The method of claim 12, wherein the metal pad has a uniform octagonal shape.

16. The method of claim 13, wherein the metal pad has an oblong octagonal shape.

17. The method of claim 12, wherein the DLD metallization structure further comprises:
a second passivation layer extending in the first direction adjacent to the DLD metallization layer, wherein the second passivation layer includes a first opening adjacent to the metal pad.

18. The method of claim 17, wherein the DLD metallization structure further comprises:
a polymer dielectric layer extending in the first direction adjacent to the second passivation layer, wherein the polymer dielectric layer includes a second opening adjacent to the first opening.

19. The method of claim 17, wherein the first opening has a first opening width of 25 micrometers (μm) and a length of 35 μm.

20. The method of claim 18, wherein the second opening has a second opening width in a first range between 10-20 micrometers (μm) and a length in a second range between 20-30 μm.
